(19) United States
(12) Patent Application Publication
(10) Pub. No.: US 2025/0038143 A1
(43) Pub. Date: Jan. 30, 2025

(54) CHIP

(71) Applicant: CHIPBOND TECHNOLOGY CORPORATION, Hsinchu (TW)

(72) Inventor: Chun-Chia Yeh, Hsinchu County (TW)

(21) Appl. No.: 18/753,556

(22) Filed: Jun. 25, 2024

(30) Foreign Application Priority Data
Jul. 25, 2023 (TW) 112127814

(51) Int. Cl. H01L 23/00; H01L 23/31

(52) U.S. Cl. CPC H01L 24/10; H01L 23/3157; H01L 24/16; H01L 2224/10125; H01L 2224/16225; H01L 2924/2064

(57) ABSTRACT

A chip provided to be flip bonded to a circuit board includes at least one bump and at least one supportive element which protrudes from an active surface of the chip and is located between the bump and a first side of the active surface. The supportive element is provided to support a lead on the circuit board to prevent the lead from contacting a metal burr protruding from the active surface or a metal cut surface exposed on a side wall of the chip. The supportive element can protect the chip and the lead from short circuit or electrical abnormality.

### CROSS-REFERENCE TO RELATED APPLICATIONS

This application claims priority to R.O.C Patent Application No. 112127814 filed Jul. 25, 2023, the disclosure of which is hereby incorporated by reference in its entirety.

### FIELD OF THE INVENTION

This invention relates to a chip which can prevent lead(s) on a circuit board from contacting metal burr or metal cut surface on the chip during bonding.

### BACKGROUND OF THE INVENTION

Referring to FIGS. 1 and 2, a dicer (not shown) is moved along a scribe line 11 of a wafer 10 to cut the wafer 10 into chips 12 during dicing process. A metal layer, e.g. circuit line or metal mark located on the scribe line, is cut to have a metal cut surface 14 on a side wall 13 of the chip 12, and a metal burr 16 may be generated from the metal cut surface 14 and protrude from an active surface 15 due to ductility of the metal layer.

As shown in FIG. 2, while a lead 21 on a circuit board is bonded to a bump 17 of the chip 12, the lead 21 may contact the metal cut surface 14 or the metal burr 16 to bring problem of short circuit or electrical abnormality.

### SUMMARY OF THE INVENTION

One object of the present invention is to provide a chip which includes at least one supportive element protruding from an active surface and provided for supporting a lead on a circuit board.

A chip of the present invention includes at least one bump and at least one supportive element which are arranged on an active surface and protrude from the active surface. The bump is provided to bond with a lead of a circuit board. The supportive element is located between the bump and a first side of the active surface and provided to support the lead. A first height of the bump is greater than or equal to a second height of the supportive element.

While the lead is bonded to the bump, the supportive element protruding from the active surface can support the lead to allow the lead to be suspended over the first side of the active surface. Thus, short circuit or electrical abnormality caused by the lead contacting metal cut surface or metal burr located on the first side of the active surface can be prevented.

### BRIEF DESCRIPTION OF DRAWINGS

FIG. 1 is top view diagram illustrating a conventional wafer.

FIG. 2 is a cross-section view diagram illustrating a conventional wafer.

FIG. 3 is a top view diagram illustrating a part of a chip in accordance with one embodiment of the present invention.

FIG. 4 is a cross-section view diagram illustrating a chip in accordance with one embodiment of the present invention.

FIG. 5 is a top view diagram illustrating a part of a chip in accordance with another embodiment of the present invention.

FIG. 6 is a cross-section view diagram illustrating a chip in accordance with another embodiment of the present invention.

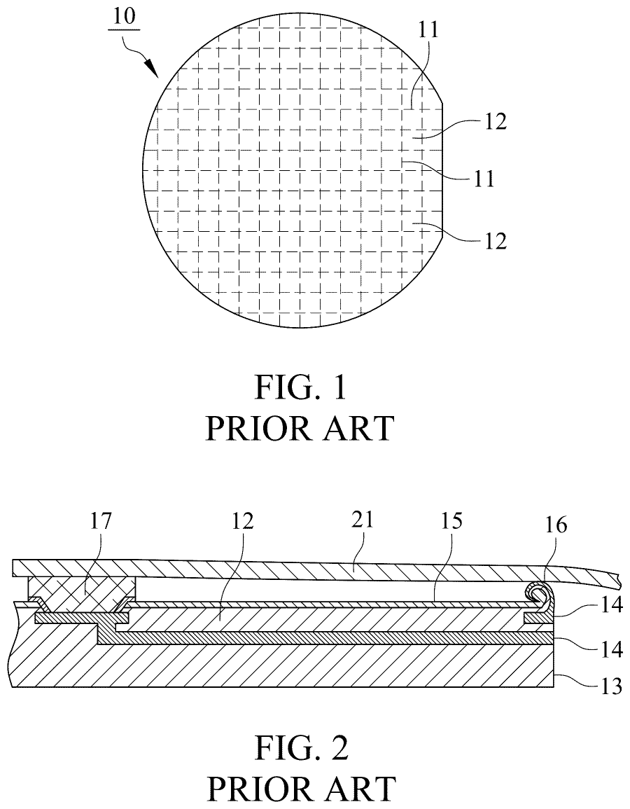

### DETAILED DESCRIPTION OF THE INVENTION

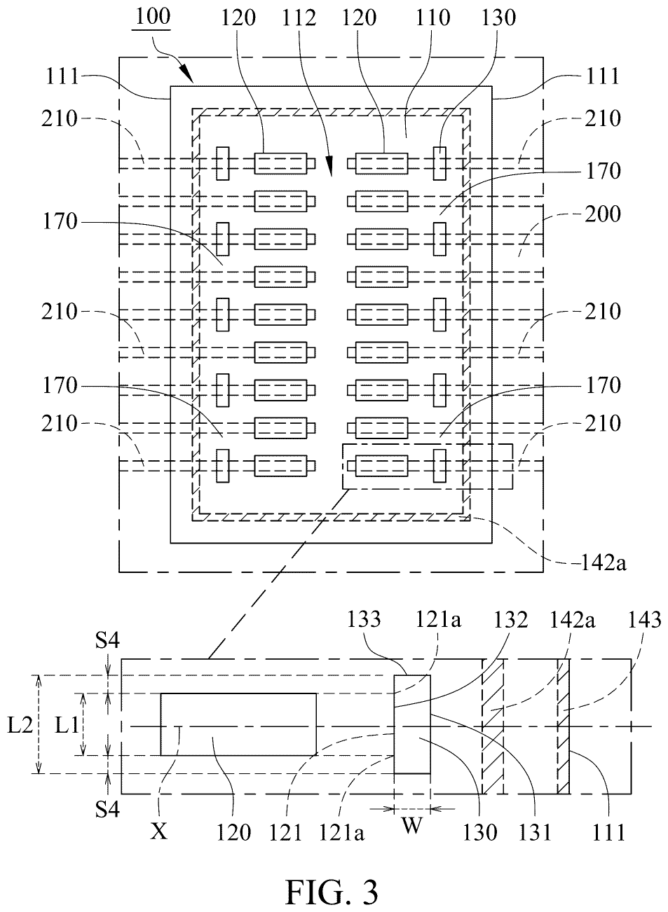

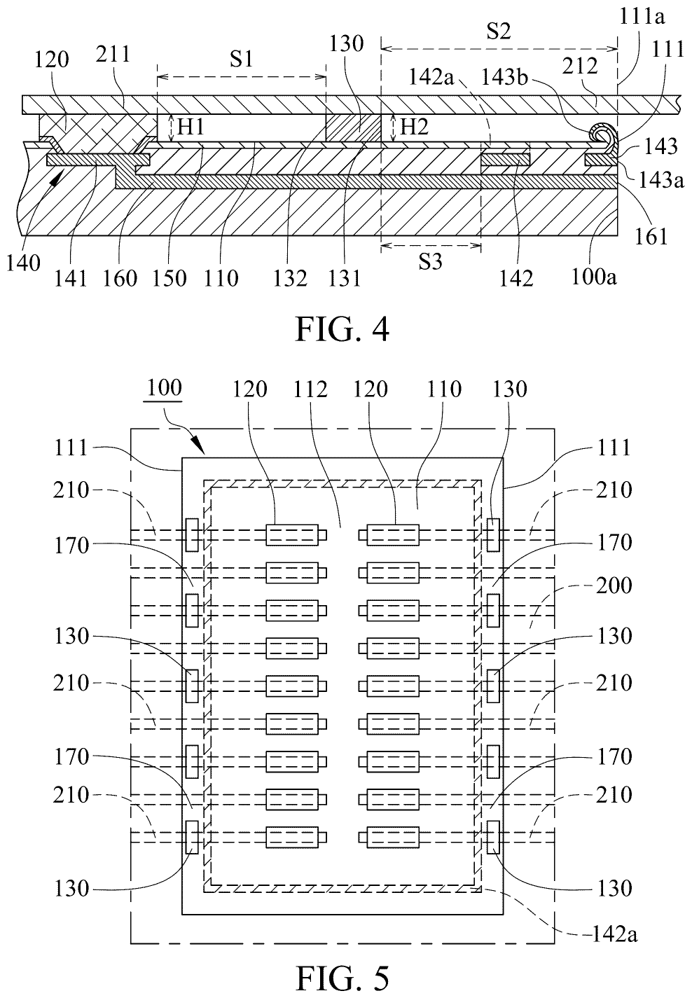

With reference to FIGS. 3 and 4, a wafer (not shown) is diced into many chips 100. Each of the chips 100 includes an active surface 110, at least one bump 120, at least one supportive element 130, a metal layer 140, a protective layer 150 and at least one circuit layer 160. The bump 120 and the supportive element 130 are arranged on the active surface 110. The bump 120 is located on a bump arrangement area 112 defined on the active surface 110 and protrudes from the active surface 110, and it is provided to bond with a lead 210 of a circuit board 200.

With reference to FIGS. 3 and 4, the metal layer 140 includes conductive pads 141, a seal ring 142 and at least one mark 143. In this embodiment, the mark 143 is located on a scribe line (not shown) of the wafer. The conductive pads 141 are connected to the circuit layer 160 and surrounded by the seal ring 142. The protective layer 150 covers the seal ring 142 and the circuit layer 160, but not cover the conductive pads 141. In this embodiment, the surface of the protective layer 150 is the active surface 110 of the chip 100, and the bump 120 is electrically connected to at least one of the conductive pads 141.

With reference to FIGS. 3 and 4, after dicing the wafer, a cut surface 143a of the mark 143 and a cut surface 161 of the circuit layer 160 are formed on a side wall 100a of the chip 100. Due to ductility of the metal layer 140 and the circuit layer 160, a metal burr 143b may be generated from the cut surface 143a of the mark 143 and protrude from the active surface 110, and a metal burr (not shown) may be generated from the cut surface 161 of the circuit layer 160 and protrude from the active surface 110.

With reference to FIGS. 3 and 4, the supportive element 130, which may be made of a polymeric material or a nonconductive material, protrudes from the active surface 110 and is located between the bump 120 and a first side 111 of the active surface 110. Preferably, each of the chips 100 includes multiple supportive elements 130 and there is a gap 170 between the adjacent supportive elements 130. The gap 170 communicates the first side 111 of the active surface 110 and the bump arrangement area 112 defined on the active surface 110 such that an underfill (not shown) can flow from the first side 111 of the active surface 110 to the bump arrangement area 112 via the gap 170 to seal the bump 120 and the lead 210 of the circuit board 200. A first height H1 of the bump 120 protruding from the active surface 110 is greater than or equal to a second height H2 of the supportive element 130 protruding from the active surface 110. In one embodiment, the first height H1 of the bump 120 is higher than the second height H2 of the supportive element 130, the difference between the first height H1 and the second height H2 is less than or equal to 7 μm, and the second height H2 of the supportive element 130 is preferably greater than or equal to 5 μm. As a bonding end 211 of the lead 210 is bonded to the bump 120, the supportive element 130 can support an exposed part 212 of the lead 210 to avoid the exposed part 212 from contacting the cut surface 143a or the metal burr 143b of the mark 143, the cut surface 161 or the metal burr of the circuit layer 160.

With reference to FIG. 4, a first distance S1 is defined from the bump 120 to the supportive element 130, a second distance S2 is defined from the supportive element 130 to an imaginary line 111a extending from the first side 111 of the active surface 110, and the quotient (S1/S2) of the first distance S1 to the second distance S2 is between 0.5 and 100. Because of the restriction of the quotient (S1/S2), the flexibility resistance of the exposed part 212 of the lead 210 can be improved to avoid the exposed part 212 from bending to contact the cut surface 143a or the metal burr 143b of the mark 143, the cut surface 161 or the metal burr of the circuit layer 160.

With reference to FIGS. 3 and 4, the seal ring 142 projects to the active surface 110 to form a seal ring projection 142a, and the supportive element 130 is located between the bump 120 and the seal ring projection 142a in this embodiment. In a direction of an axis line X extending from the supportive element 130 toward the first side 111 of the active surface 110, a width W of the supportive element 130 is preferably greater than or equal to 5 μm and is less than or equal to the distance from the bump 120 to the seal ring projection 142a. The supportive element 130 has an outer sider wall 131 adjacent to the first side 111 of the active 110 and an inner side wall 132 adjacent to the bump 120, a third distance S3 defined from the outer side wall 131 to the seal ring projection 142a is greater than or equal to 1 μm and less than or equal to 100 μm, and the first distance S1 defined from the inner side wall 132 to the bump 120 is greater than or equal to 1 μm and less than or equal to 100 μm.

With reference to FIGS. 3 and 4, in a direction vertical to the axis line X, a first length L1 of the bump 120 is less than or equal to a second direction L2 of the supportive element 130. The bump 120 projects to the supportive element 130 in the direction of the axis line X to form a bump projection 121. A third side 133 of the supportive element 130 is adjacent to a second side 121a of the bump projection 121, and in the direction vertical to the axis line X, a fourth distance S4 from the second side 121a to the third side 133 is greater than or equal to 1 μm and less than or equal to 10 μm. Even if the lead 210 is bonded to the bump 120 obliquely, the supportive element 130 still can support the exposed part 212 of the lead 210.

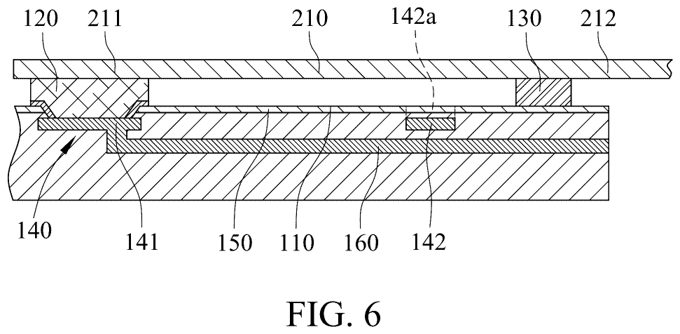

With reference to FIGS. 4 to 6, the supportive element 130 may be arranged between the seal ring projection 142a and the first side 111 of the active surface 110 in another embodiment. As the bonding end 211 of the lead 210 is bonded to the bump 120, the supportive element 130 can support the exposed part 212 of the lead 210 to avoid the exposed part 212 from contacting the cut surface 143a of the mark 143, the metal burr 143b from the cut surface 143a, the cut surface 161 of the circuit layer 160 and the metal burr from the cut surface 161. In other embodiment(s), the outer side wall 131 of the supportive element 130 and the side wall 100a of the chip 100 are flush (not shown).

In the present invention, the supportive element 130 protruding the active surface 110 is provided to support the lead 210 bonded to the bump 120 such that the exposed part 212 of the lead 210 can be located above the first side 111 of the active surface 110 and avoid to contact the cut surface and/or the metal burr located on the first side 111 of the active surface 110 to cause short circuit or electrical abnormality.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A chip comprising:
at least one bump arranged on an active surface and protruding from the active surface, the at least bump is configured to bond with a lead on a circuit board; and
at least one supportive element arranged on the active surface, protruding from the active surface and located between the at least one bump and a first side of the active surface, the at least one supportive element is configured to support the lead, wherein a first height of the at least one bump is greater than or equal to a second height of the at least one supportive element.

2. The chip in accordance with claim 1, wherein the first height is greater than the second height, and a difference between the first and second heights is less than or equal to 7 μm.

3. The chip in accordance with claim 2, wherein the second height is greater than or equal to 5 μm.

4. The chip in accordance with claim 1, wherein a first distance is defined from the at least one bump to the at least one supportive element, a second distance is defined from the at least one supportive element to an imaginary line extending from the first side of the active surface, and a quotient of the first and second distances is between 0.5 and 100.

5. The chip in accordance with claim 4, wherein a width of the at least one supportive element in a direction of an axis line extending from the at least one supportive element toward the first side of the active surface is greater than or equal to 5 μm.

6. The chip in accordance with claim 1 further comprising a metal layer and a protective layer, wherein the metal layer includes a plurality of conductive pads and a seal ring, the plurality of conductive pads are surrounded by the seal ring, the seal ring is covered by the protective layer, the plurality of conductive pads are not covered by the protective layer, a surface of the protective layer is the active surface, the at least one bump is electrically connected to one of the plurality of conductive pads, the seal ring projects to the active surface to form a seal ring projection, and the at least one supportive element is located between the at least one bump and the seal ring projection.

7. The chip in accordance with claim 6, wherein an outer side wall of the at least one supportive element is adjacent to the first side of the active surface, a third distance between the outer side wall and the seal ring projection is greater than or equal to 1 μm.

8. The chip in accordance with claim 7, wherein an inner side wall of the at least one supportive element is adjacent to the at least one bump, a first distance between the inner side wall and the at least one bump is greater than or equal to 1 μm.

9. The chip in accordance with claim 6 comprising a plurality of supportive elements, wherein a gap located between the adjacent supportive elements communicates the first side of the active surface and a bump arrangement area defined on the active surface, the at least one bump is arranged on the bump arrangement area.

10. The chip in accordance with claim 1 further comprising a metal layer and a protective layer, wherein the metal layer includes at least one conductive pad and a seal ring, the at least one conductive pad is surrounded by the seal ring, the seal ring is covered by the protective layer, the at least one conductive pad is not covered by the protective layer, a surface of the protective layer is the active surface, the at least one bump is electrically connected to the at least one conductive pad, the seal ring projects to the active surface to form a seal ring projection, and the at least one supportive element is located between the seal ring projection and the first side of the active surface.

11. The chip in accordance with claim 10 comprising a plurality of supportive elements, wherein a gap located between the adjacent supportive elements communicates the first side of the active surface and a bump arrangement area defined on the active surface, the at least one bump is arranged on the bump arrangement area.

12. The chip in accordance with claim 10, wherein an outer side wall of each of the plurality of supportive elements and a side wall of the chip are flush.

13. The chip in accordance with claim 1, wherein an outer side wall of the at least one supportive element and a side wall of the chip are flush.

14. The chip in accordance with claim 1, wherein the at least one bump projects to the at least one supportive element in a direction of an axis line extending from the at least one supportive element toward the first side of the active surface, a first length of the at least one bump is less than or equal to a second length of the at least one supportive element in a direction vertical to the axis line.

15. The chip in accordance with claim 14, wherein the at least one bump projects to the at least one supportive element to form a bump projection, the at least one supportive element has a third side adjacent to a second side of the bump projection, a fourth distance between the second and third sides is greater than or equal to 1 μm in the direction vertical to the axis line.
